(19) United States
(12) Patent Application Publication
(10) Pub. No.: US 2004/0166625 A1
(43) Pub. Date: Aug. 26, 2004

(54) Method for increasing the Beta of PNP BJT device in CMOS process

(75) Inventor: Tong-Hsin Lee, Taipei Hsien (TW)

Correspondence Address: ARENT FOR KINTNER PLOTKIN & KAHN, PLLC, Suite 400, 1050 Connecticut Avenue, N.W., Washington, DC, 20036-5339, US

(73) Assignee: UNITED MICROELECTRONICS CORP

(21) Appl. No.: 10/372,973

(22) Filed: Feb. 26, 2003

(51) Int. Cl. H01L 21/8238

(52) U.S. Cl. 438/231; 438/202

(57) ABSTRACT

A method for improving the Beta (β) of a parasitic PNP bipolar junction transistor (BJT) in a conventional CMOS process includes the steps of: providing a P-type substrate having a shallow region corresponding to the P⁺ electrode of the parasitic PNP BJT and the P⁺ electrode is located within and in contact with an N-well; forming an electrostatic discharge (ESD) mask layer on the P-type substrate, wherein the mask layer has a pattern exposing an area corresponding to the P⁺ electrode of the PNP parasitic BJT, and exposing one electrode of an ESD device; and implanting P⁺ ions to the P-type substrate, thereby deepening a P/N junction of the P⁺ electrode of the parasitic BJT and the N-well.

### BACKGROUND OF THE INVENTION

1. Field of the Invention

This invention generally relates to the field of improving the Beta (β) of a parasitic PNP bipolar junction transistor (BJT) in a complementary metal oxide semiconductor (CMOS) process. More particularly, the present invention relates to a method to deepen the P′/N-well junction depth of the parasitic PNP BJT in an electrostatic discharge (ESD) implanting process.

2. Description of the Prior Art

The parasitic PNP BJT has commonly been used in a bandgap voltage circuit for a conventional CMOS process, and using the CMOS process to make the bandgap voltage circuit benefits from the cost of savings more than by using a precision-trimmed bipolar process does. However, the β of the parasitic PNP BJT is normally poorer than a preferred one due to the compatibility of the CMOS process, and it is inversely proportional to the base width, which is controlled by N-well doping concentration and P⁺/N-well junction depth.

Hence, there are two ways for improving the β of the parasitic PNP BJT in the conventional CMOS process: one is to dope lighter concentration into the N-well; the other one is to make the P⁺/N-well junction deeper. Nevertheless, these two ways can respectively cause a poorer P⁺/P-well isolation and a poor device roll-off characteristic although the β of the parasitic PNP BJT is improved in the CMOS process.

According to the conventional CMOS process, particularly, making the P⁺/N-well junction of the parasitic PNP BJT deeper to improve the β in a normal P⁺ junction implanting process can result in all transistors, not only the parasitic PNP BJT, on the wafer having deeper junctions, and this situation causes a short channel effect and a poor device roll-off characteristic. Otherwise, making the P⁺/N-well junction of the parasitic PNP BJT deeper after the normal P⁺ junction implanting process needs additional masks and processes, and this procedure can make extra costs compared to the conventional CMOS process.

As shown in FIG. 1, after a normal P⁺ junction implanting process, a P-type substrate 100 includes spaced-apart N⁺ regions 110 and 120, a channel region (not numbered) between the spaced-apart N⁺ regions 110 and 120, shallow trench isolation (STI) structures 1501 and 1502 contiguous with the spaced-apart N⁺ regions 110 and 120, respectively, and a gate structure 160 positioned over the channel region. The P-type substrate 100 also includes an N-well region 1302 and a P⁺ region 1301 within and in contact with the N-well region 1302 to form a P⁺/N-well junction, and a STI structure 1503 contiguous with the P⁺/N-well junction. Wherein, the P⁺ region 1301, the N-well region 1302, and the P-type substrate 100 form a parasitic PNP BJT.

As shown in FIG. 2, an ESD implanting process is used to decrease the N⁺/P-well junction breakdown voltage. The dopants, boron (B) at a dose of 1E13˜1E14 atoms/cm², are directly implanted into the spaced-apart N⁺ regions 110 and 120 at an energy of 30˜50 KeV. However, the region 130 of the P⁺/N-well junction of the parasitic PNP BJT cannot benefit from the ESD implanting process since the region 130 is covered by photoresist 140.

As shown in FIG. 3, after the ESD implanting process, ESD devices 1101 and 1201 are formed under the spaced-apart N⁺ regions 110 and 120, respectively. By doing so, the N⁺/P-well junction breakdown voltage can be decreased. The junction depth of the P⁺ region 1301 and the N-well region 1302 has no change after the ESD implanting process and still retains at the same depth as before, and hence the β of the parasitic PNP BJT is still poor.

In view of the drawbacks mentioned with the prior art process, there is a continued need to develop new and improved processes that overcome the disadvantages associated with prior art processes. The advantages of this invention are that it solves the problems mentioned above.

### SUMMARY OF THE INVENTION

In accordance with the present invention, a method to improve the β of the parasitic PNP BJT in the conventional CMOS process substantially obviates one or more of the problems resulted from the limitations and disadvantages of the prior art mentioned in the background.

Accordingly, one object of the present invention is to provide a method for improving the β of the parasitic PNP BJT in the conventional CMOS process without additional masks and processes.

Another object is to provide a method for improving the β of the parasitic PNP BJT in the conventional CMOS process by deepening the P⁺/N-well junction of the parasitic PNP BJT in the ESD implanting process.

Still another object is to provide a method for improving the β of the parasitic PNP BJT in the conventional CMOS process without any side effects on other normal P⁺ junctions.

According to the objects mentioned above, the present invention provides a method for improving the β of the parasitic PNP BJT in the conventional CMOS process, including: forming an exposing area by using an ESD mask with an extra exposing area corresponding to the P⁺/N-well junction of the parasitic PNP BJT; performing an ESD implanting process on both forming ESD devices and deepening the P⁺/N-well junction. Herein, the ESD mask can be used in patterning the exposing areas for the ESD devices and the P⁺/N-well junction at the same time. Hence, the dopants, boron (B) at a dose of 1E13˜1E14 atoms/cm², can be implanted into not only the spaced-apart N⁺ regions to form the ESD devices but also the parasitic PNP BJT to deepen the P⁺/N-well junction in the ESD implanting process. This is, the extra ESD implanting process to the parasitic PNP BJT results in a deeper P⁺/N-well junction and a higher β without any side effect on other normal P⁺ junctions. In other words, the method uses the adjusted masks and the same process steps without any additional masks and processes compared to a conventional CMOS process.

### BRIEF DESCRIPTION OF THE DRAWINGS

The foregoing aspects and many of the attendant advantages of this invention will become more readily appreciated as the same becomes better understood with reference to the following detailed description, when taken in conjunction with the accompanying drawings, wherein:

FIG. 1 shows cross-sectional views of a parasitic PNP BJT in a CMOS after a normal P⁺ implanting process;

FIG. 2 and FIG. 3 show cross-sectional views of the parasitic PNP BJT in the CMOS in an ESD implanting process and after the ESD implanting process, respectively;

FIG. 4 shows cross-sectional views of a parasitic PNP BJT in a CMOS after a normal P⁺ implanting process;

FIG. 5 shows cross-sectional views of the parasitic PNP BJT in the CMOS in an ESD implanting process in accordance with the present invention; and

FIG. 6 shows cross-sectional views of the improved parasitic PNP BJT in the CMOS in accordance with the present invention.

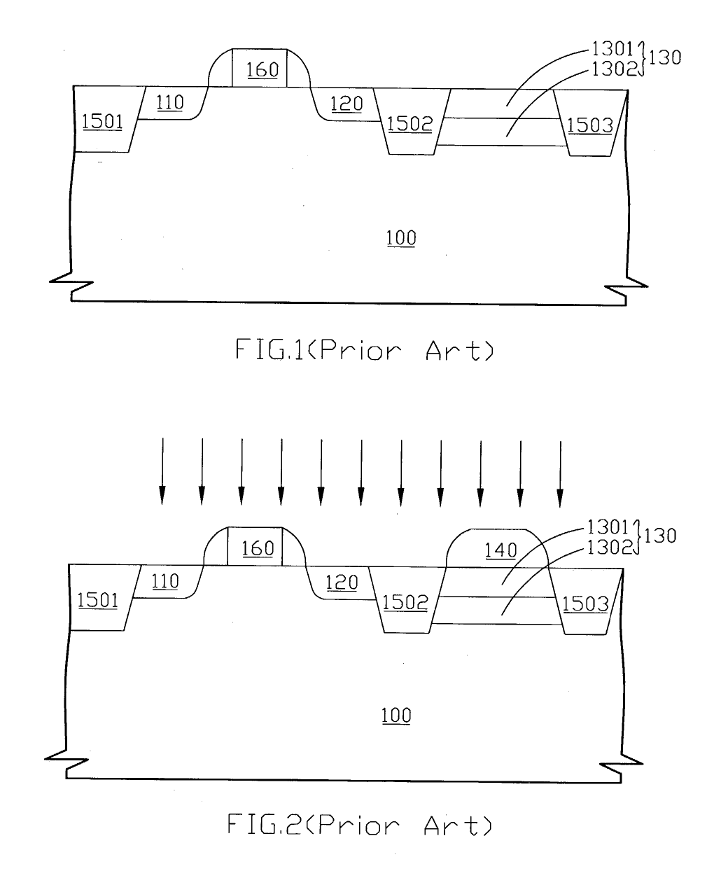

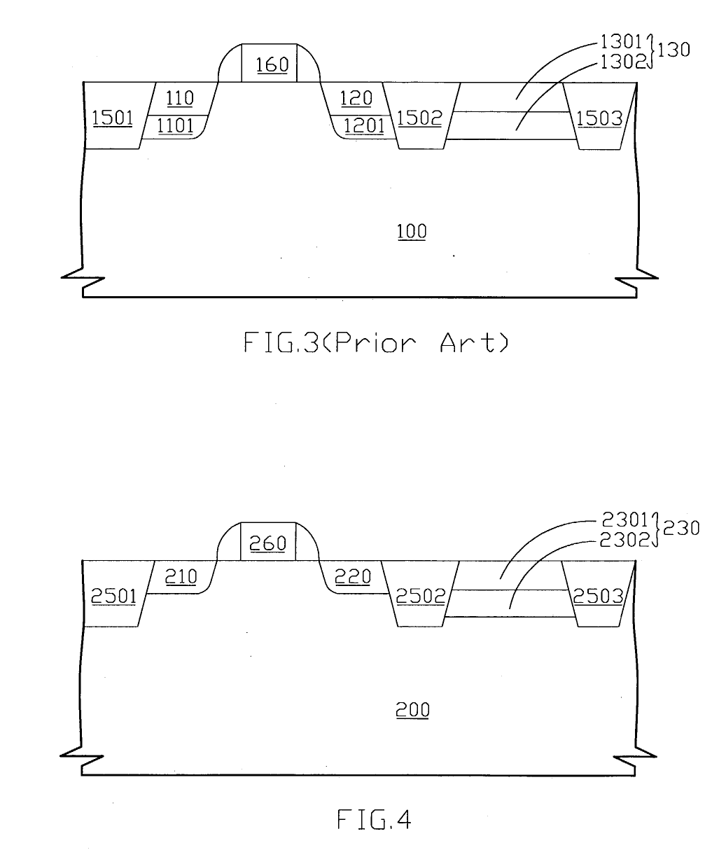

### DESCRIPTION OF THE PREFERRED EMBODIMENT

Some embodiments of the invention will now be described in greater detail. Nevertheless, it should be noted that the present invention can be practiced in a wide range of other embodiments besides those explicitly described, and the scope of the present invention is expressly not limited except as specified in the accompanying claims.

Moreover, it should be noted that the drawings are in greatly simplified form and they are not drawn to scale and dimensions have been exaggerated in order to provide a clear illustration and understanding of the present invention.

In accordance with the present invention, a method is provided for improving the β of the parasitic BJT in the conventional CMOS process without any extra masks, processes, and side effects on normal junctions, including the steps of: providing a substrate having an area corresponding to a first electrode of a parasitic BJT, a second electrode of the parasitic BJT being in contact between the first electrode and a third electrode of the parasitic BJT, and another areas corresponding to the electrodes of ESD devices; forming a mask layer on the substrate, wherein the mask layer including photoresist has a pattern exposing areas corresponding to the first electrode of the parasitic BJT and to the electrodes of the ESD devices; and implanting ions to the substrate, wherein implanted ions have the same conductivity type as the first electrode of the parasitic BJT, having concentration of about 1E13˜1E14 atoms/cm², and are implanted with an energy of about 30˜50 KeV, thereby deepening a junction of the first electrode and the second electrode of the parasitic BJT and forming the ESD devices.

As shown in FIG. 4, after a normal P⁺ junction implanting process, a P-type substrate 200 includes spaced-apart N⁺ regions 210 and 220, a channel region (not numbered) between the spaced-apart N⁺ regions 210 and 220, shallow trench isolation (STI) structures 2501 and 2502 contiguous with the spaced-apart N⁺ regions 210 and 220, respectively, and a gate structure 260 positioned over the channel region. The P-type substrate 200 also includes an N-well region 2302 and a P⁺ region 2301 within and in contact with the N-well region 2302 to form a P⁺/N-well junction, and a STI structure 2503 contiguous with the P⁺/N-well junction. Wherein, the P⁺ region 2301, the N-well region 2302, and the P-type substrate 200 form a parasitic PNP BJT.

As shown in FIG. 5, an ESD mask layer including photoresist (cannot be seen in FIG. 5 since the areas in FIG. 5 need to be exposed) is formed on the P-type substrate. Furthermore, the ESD mask layer has a pattern exposing the areas corresponding to the P⁺ region 2301 of the PNP parasitic BJT and to the electrodes 210 and 220 of ESD devices. Implanted ions, boron (B) at a dose of 1E13˜1E14 atoms/cm², are directly implanted into the spaced-apart N⁺ regions 210 and 220 as well as the region 230 of the P⁺/N-well junction of the parasitic PNP BJT at an energy of 30˜50 KeV.

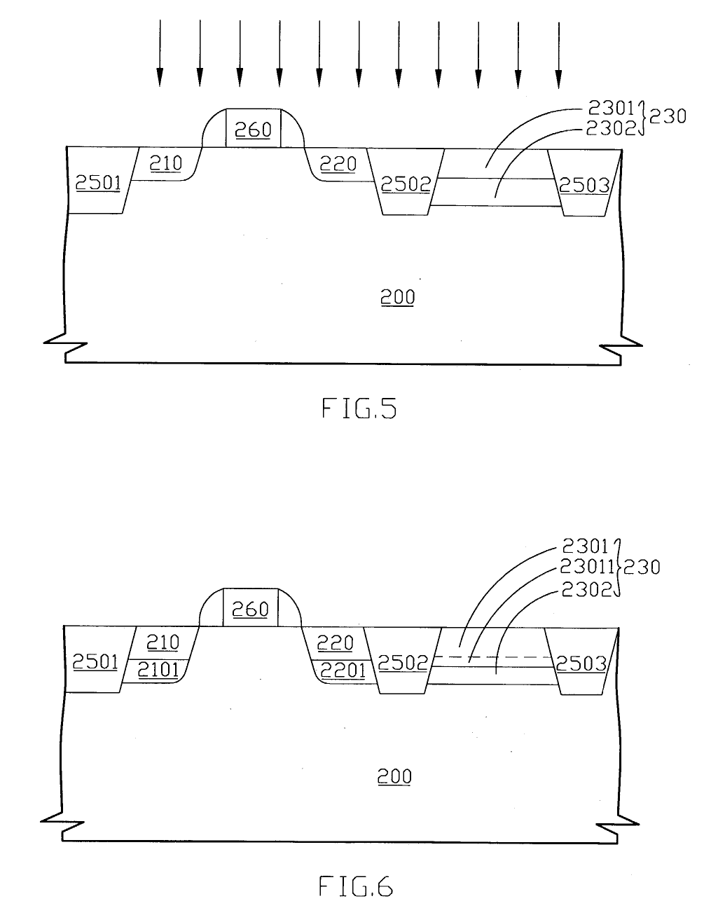

As shown in FIG. 6, after the ESD implanting process, the ESD devices 2101 and 2201 are formed under the spaced-apart N⁺ regions 210 and 220, respectively. By doing so, the N⁺/P-well junction breakdown voltage can be decreased. Moreover, the junction depth of the P⁺ region 2301 becomes deeper (2301 and 23011). Hence, the β of the parasitic PNP BJT is improved by deepening the P⁺/N-well junction depth. Further, there are no side effects, for example, a short channel effect, on a normal P′ junction since the implanted ions are only implanted into the ESD devices regions and the parasitic PNP BJT region.

The method in accordance with the present invention uses the same processes and masks without any extra cost compared to the conventional CMOS process. A key issue for the method is to adjust an extra exposing area corresponding to the parasitic PNP BJT on the ESD mask so that the photoresist can be patterned and removed to form an exposing area on the parasitic PNP BJT during the ESD implanting process. As to the other process steps are the same as those in the convention CMOS process.

However, it is to be understood and appreciated that the process steps and structures described above do not cover a complete process flow. The present invention can be practiced in conjunction with various fabrication techniques that are used in the art, and only so much of the commonly practiced process steps are included herein as are necessary to provide an understanding of the present invention.

Although specific embodiments have been illustrated and described, it will be obvious to those skilled in the art that various modifications may be made without departing from what is intended to be limited solely by the appended claims.

What is claimed is:

1. A method for increasing the Beta (β) of a parasitic bipolar junction transistor (BJT) in a CMOS, said method comprising:
providing a substrate having an area corresponding to a first electrode of a parasitic BJT, a second electrode of said parasitic BJT being in contact between said first electrode and a third electrode of said parasitic BJT;
forming a mask layer on said substrate, wherein said mask layer has a pattern exposing an area corresponding to said first electrode of said parasitic BJT; and
implanting ions to said substrate, wherein implanted ions have the same conductivity type as said first electrode of said parasitic BJT, thereby deepening a junction of said first electrode and said second electrode of said parasitic BJT.

2. The method according to clam 1, further comprising another area, within said substrate, which corresponds to one electrode of an electrostatic discharge (ESD) device.

3. The method according to claim 2, wherein said ions are also implanted into said area corresponding to said electrode of said ESD device, thereby forming another electrode of said ESD device, resulting in said ESD device.

4. The method according to claim 3, wherein said mask layer is an ESD mask layer used in an ESD process.

5. The method according to claim 1, wherein said mask layer comprises photoresist.

6. The method according to claim 1, wherein said implanted ions comprises boron (B).

7. The method according to claim 1, wherein said implanted ions have concentration of about 1E13˜1E14 atoms/cm².

8. The method according to claim 1, wherein said ions are implanted with energy of about 30˜50 KeV.

9. A method for increasing the Beta (β) of a parasitic PNP bipolar junction transistor (BJT) in a CMOS, said method comprising:
providing a P-type substrate, wherein said P-type substrate includes a shallow region corresponding to a P⁺ electrode of a parasitic PNP BJT, said P⁺ electrode is located within and in contact with an N-well, thereby said P⁺ electrode, said N-well, and said P-type substrate forming said parasitic PNP BJT;
forming an electrostatic discharge (ESD) mask layer on said P-type substrate, wherein said mask layer has a pattern exposing an area corresponding to said P⁺ electrode of said PNP parasitic BJT, and exposing one electrode of an ESD device; and
implanting P⁺ ions to said P-type substrate, thereby deepening a P/N junction of said P⁺ electrode of said parasitic BJT and said N-well.

10. The method according to claim 9, wherein said ions are also implanted into said one electrode of said ESD device, thereby forming another electrode of said ESD device, resulting in said ESD device.

11. The method according to claim 9, wherein said ESD mask layer comprises photoresist.

12. The method according to claim 9, wherein said implanted ions comprise boron (B).

13. The method according to claim 9, wherein said implanted ions have concentration of about 1E13˜1E14 atoms/cm².

14. The method according to claim 9, wherein said ions are implanted with energy of about 30˜50 KeV.
